(19) United States
(12) Patent Application Publication
(10) Pub. No.: US 2025/0287851 A1
(43) Pub. Date: Sep. 11, 2025

(54) MAGNETIC DEVICE

(71) Applicant: SP-AITH Limited, Sheung Wan (CN)

(72) Inventor: Hiroaki Yoda, Tsukuba-shi Ibaraki (JP)

(73) Assignee: SP-AITH Limited, Sheung Wan (CN)

(21) Appl. No.: 19/217,612

(22) Filed: May 23, 2025

Related U.S. Application Data
(63) Continuation of application No. PCT/JP2022/044174, filed on Nov. 30, 2022.

(51) Int. Cl. H10N 50/80; H10N 50/10

(52) U.S. Cl. CPC H10N 50/80; H10N 50/10

(57) ABSTRACT

A magnetic device includes a first element portion including a first magnetic layer, a first non-magnetic member, a first magnetic member, and a first intermediate layer. The first non-magnetic member includes at least one of first and second materials. The first material includes first and second elements. The first element includes one of first and second type elements. The second element includes at least one element selected from the group consisting of oxygen and nitrogen. The first type element includes at least one element selected from the group consisting of Ru, Ta, Mo, W, Hf, Cr, Cu, Pd, V, Ti, and Zn. The second type element includes at least one selected from the group consisting of Mg and Al. The second material includes a third element and a fourth element. The third element includes at least one selected from the group consisting of Pt, Cu, and Hf.

### CROSS-REFERENCE TO RELATED APPLICATIONS

This is a continuation application of International Application PCT/JP2022/044174, filed on Nov. 30, 2022; the entire contents of which are incorporated herein by reference.

### FIELD

Embodiments described herein relate generally to a magnetic device.

### BACKGROUND

Magnetic devices including a magnetic layer are used in a variety of applications. Stable operation is desired in the magnetic devices.

### BRIEF DESCRIPTION OF THE DRAWINGS

FIG. 1 is a schematic cross-sectional view illustrating a magnetic device according to a first embodiment;

FIG. 2 is a schematic perspective view illustrating the magnetic device according to the first embodiment;

FIG. 3 is a schematic cross-sectional view illustrating a magnetic device according to the first embodiment;

FIGS. 4A and 4B are schematic cross-sectional views illustrating a magnetic device according to the first embodiment;

FIGS. 5A and 5B are schematic cross-sectional views illustrating a magnetic device according to the first embodiment;

FIGS. 6A and 6B are schematic cross-sectional views illustrating a magnetic device according to the first embodiment;

FIGS. 7A and 7B are schematic cross-sectional views illustrating a magnetic device according to the first embodiment;

FIG. 8 is a schematic cross-sectional view illustrating a magnetic device according to a second embodiment; and

FIG. 9 is a schematic cross-sectional view illustrating a magnetic device according to a third embodiment.

### DETAILED DESCRIPTION

According to one embodiment, a magnetic device includes a first element portion. The first element portion includes a first magnetic layer, a first non-magnetic member, a first magnetic member, and a first intermediate layer. The first non-magnetic member is conductive. A direction from the first magnetic layer to the first non-magnetic member is along a first direction. The first magnetic member is provided between the first magnetic layer and the first non-magnetic member, and is in contact with the first non-magnetic member. The first intermediate layer is non-magnetic and is provided between the first magnetic layer and the first magnetic member. The first non-magnetic member includes at least one of a first material or a second material. The first material includes a first element and a second element. The first element includes one of a first type element and a second type element. The second element includes at least one element selected from the group consisting of oxygen and nitrogen. The first type element includes at least one element selected from the group consisting of Ru, Ta, Mo, W, Hf, Cr, Cu, Pd, V, Ti, and Zn. The second type element includes at least one selected from the group consisting of Mg and Al. The second material includes a third element and a fourth element. The third element includes at least one selected from the group consisting of Pt, Cu, and Hf, the fourth element including Al.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

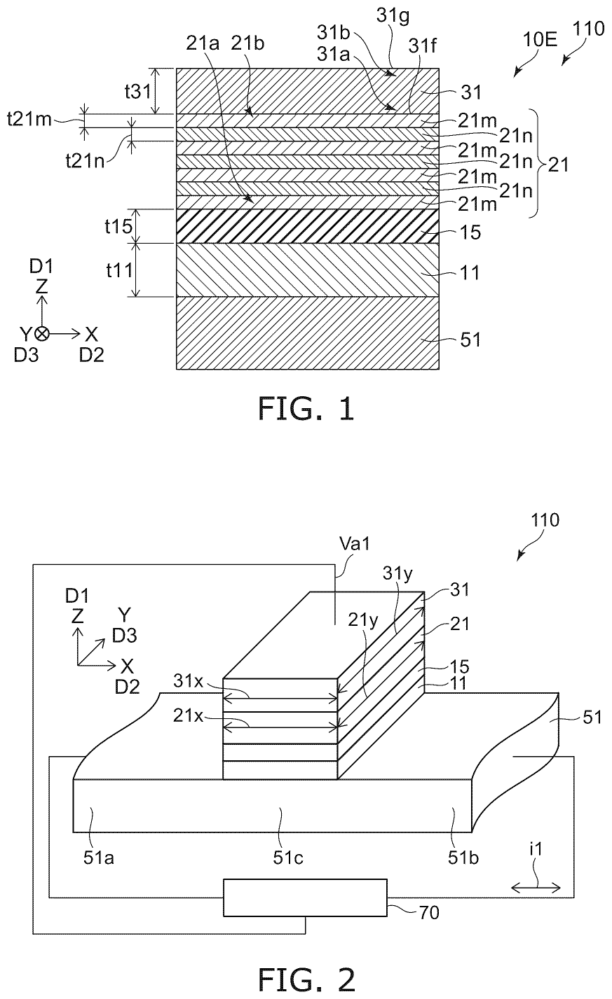

FIG. 1 is a schematic cross-sectional view illustrating a magnetic device according to a first embodiment.

FIG. 2 is a schematic perspective view illustrating the magnetic device according to the first embodiment.

A magnetic device 110 according to the embodiment includes a first element portion 10E. The first element portion 10E includes a first magnetic layer 11, a first non-magnetic member 31, a first magnetic member 21, and a first intermediate layer 15.

The first non-magnetic member 31 is conductive. A direction from the first magnetic layer 11 to the first non-magnetic member 31 is along a first direction D1.

The first direction D1 is defined as a Z-axis direction. One direction perpendicular to the Z-axis direction is defined as an X-axis direction. A direction perpendicular to the Z-axis and X-axis directions is defined as a Y-axis direction.

The first magnetic member 21 is provided between the first magnetic layer 11 and the first non-magnetic member 31. The first magnetic member 21 is in contact with the first non-magnetic member 31. The first intermediate layer 15 is provided between the first magnetic layer 11 and the first magnetic member 21. The first intermediate layer 15 is non-magnetic. For example, the first intermediate layer 15 may be in contact with the first magnetic layer 11 and the first magnetic member 21.

The first non-magnetic member 31 includes at least one of a first material or a second material. The first material includes a first element including one of a first type element and a second type element, and a second element including at least one selected from the group consisting of oxygen and nitrogen. The first type element includes at least one selected from the group consisting of Ru, Ta, Mo, W, Hf, Cr, Cu, Pd, V, Ti, and Zn. The second type element includes at least one selected from the group consisting of Mg and Al. The second material includes a third element including at least one selected from the group consisting of Pt, Cu, and Hf, and a fourth element including Al. For example, the first non-magnetic member 31 includes Ru and oxygen. For example, the first non-magnetic member 31 includes Al, Pt, etc. This provides stable operation, as described below. Examples of the first material and the second material will be described later.

In the embodiment, the first intermediate layer 15 includes, for example, at least one selected from the group consisting of MgO, CaO, SrO, TiO, VO, NbO, and Al₂O₃. The first element portion 10E is, for example, a TMR (Tunnel Magneto Resistance) element.

The first magnetic layer 11 is, for example, a magnetization free layer. The first magnetic member 21 is, for example, a magnetization reference layer. The magnetization of the first magnetic member 21 is less likely to change than the magnetization of the first magnetic layer 11.

The first magnetic layer 11 includes at least one selected from the group consisting of Fe, Co, and Ni. The first magnetic layer 11 may further include boron. The first magnetic layer 11 is, for example, a ferromagnetic layer.

As shown in FIG. 1, in one example, the first magnetic member 21 includes a plurality of first magnetic films 21m and a plurality of first non-magnetic films 21n. In the first direction D1, one of the plurality of first non-magnetic films 21n is located between one of the plurality of first magnetic films 21m and another one of the plurality of first magnetic films 21m. One of the plurality of first magnetic films 21m is located between one of the plurality of first non-magnetic films 21n and another one of the plurality of first non-magnetic films 21n. For example, the first magnetic films 21m and the first non-magnetic films 21n are alternately provided. The first magnetic film 21m contacts the first non-magnetic film 21n.

For example, the first magnetic member 21 may be a synthetic anti-ferromagnetic (SAF) layer. One of the plurality of first magnetic films 21m may be antiferromagnetically coupled to another one of the plurality of first magnetic films 21m. For example, the SAF structure stabilizes the magnetization of the plurality of first magnetic films 21m The magnetization of the first magnetic member 21 is stabilized.

For example, the first magnetic member 21 may satisfy the following first condition or second condition. In the first condition, one of the plurality of first non-magnetic films 21n includes Ru. The thickness t21n of one of the plurality of first non-magnetic films 21n along the first direction D1 is not less than 0.2 nm and not more than 2 nm.

In the second condition, one of the plurality of first non-magnetic films 21n includes Ir. The thickness t21n of one of the plurality of first non-magnetic films 21n along the first direction D1 is not less than 0.2 nm and not more than 2 nm.

Such first condition or second condition makes it easier to obtain antiferromagnetic coupling. Meanwhile, the plurality of first magnetic films 21m include at least one selected from the group consisting of Fe, Co, and Ni. The plurality of first magnetic films 21m may further include boron. The thickness t21m of the plurality of first magnetic films 21m along the first direction D1 may be, for example, not less than 0.2 nm and not more than 5 nm.

As already explained, in one example, the first magnetic member 21 functions as a magnetization reference layer. In a reference example, an antiferromagnetic member (e.g., IrMn or PtMn) is provided on the first magnetic member 21. This allows the magnetization of the first magnetic member 21 to be fixed in a desired direction. In this reference example, it was found that the magnetization of the first magnetic member 21 is likely to become unstable when the size of the magnetic element (e.g., the first element portion 10E) becomes smaller. For example, when the size of the magnetic element (e.g., the first element portion 10E) becomes smaller, the size of the magnetic element approaches the size of the crystal grains included in the antiferromagnetic member. This causes the state of the crystal grains included in the antiferromagnetic member in the magnetic element to become non-uniform. As a result, it is considered that the magnetization of the first magnetic member 21 becomes unstable.

In contrast, in the embodiment, the first non-magnetic member 31 above-mentioned is provided instead of the antiferromagnetic member. The first non-magnetic member 31 includes the above-mentioned first material or second material. The first material includes the first element and the second element. For example, it is considered that the volume of the first non-magnetic member 31 changes when the second element (oxygen and/or nitrogen) is introduced into a member including the first element. As a result, stress is generated in the first non-magnetic member 31. The second material includes the third element and the fourth element (Al). For example, it is considered that the volume of the first non-magnetic member 31 changes when the third element (Pt, Cu, and/or Hf, etc.) is introduced into a member including the fourth element (Al). As a result, stress is generated in the first non-magnetic member 31. It is considered that the stress is applied to the first magnetic member 21, and the magnetization direction of the first magnetic member 21 is controlled.

In the first non-magnetic member 31, the above-mentioned crystal grain problem in the antiferromagnetic member does not occur. Even if the size of the magnetic element (for example, the first element portion 10E) is reduced, the magnetization of the first magnetic member 21 is stably controlled.

By stabilizing the magnetization of the first magnetic member 21, the characteristics of the magnetic element are stabilized. For example, the stability of the characteristics of the first magnetic member 21 is improved. For example, a large resistance change rate is obtained. For example, a large read signal is obtained. For example, stress is applied to the first magnetic layer 11. For example, good retention is obtained. Stable characteristics can be maintained even if the size of the first element portion 10E is reduced. According to the embodiment, a magnetic device capable of stable operation can be provided.

In the embodiment, for example, the first non-magnetic member 31 can apply stress to the first magnetic member 21. The stress may be, for example, one of tensile stress and compressive stress. The stress may have a component in a direction (a direction along the X-Y plane) that crosses the first direction D1.

As described above, the first material includes a first element including one of a first type element and a second type element, and a second element including at least one selected from the group consisting of oxygen and nitrogen. The first type element includes at least one selected from the group consisting of Ru, Ta, Mo, W, Hf, Cr, Cu, Pd, V, Ti, and Zn. For example, when oxygen is introduced into a film of the first type element, the volume of the film increases. The increase in volume is considered to be due to, for example, the difference between the structure (e.g., crystal structure) of the film of the first type element and the structure (e.g., crystal structure) of the film including the first type element and oxygen.

The effect of the increase in volume is large for Ru, Ta, Mo, or W. The effect of the increase in volume is moderate for Hf, Cr, Cu, and Pd. The effect of the increase in volume is relatively small for V, Ti, or Zn.

The second type element includes at least one selected from the group consisting of Mg and Al. For example, when oxygen is introduced into a film of the second type element, the volume of the film decreases. The decrease in volume is thought to be due to, for example, the difference between the structure (e.g., crystal structure) of the film of the second type element and the structure (e.g., crystal structure) of the film including the second type element and oxygen.

Among the various elements mentioned above, Hf, Al, and Mg are difficult to mix with the layer including Co, Fe, etc. included in the first magnetic member 21. In a case where the first non-magnetic member 31 includes Hf, Al, or Mg, stress can be applied to the first magnetic member 21 while suppressing adverse effects on the characteristics of the first magnetic member 21.

As described above, when the first non-magnetic member 31 includes the first material or the second material, stress is generated between the first non-magnetic member 31 and the first magnetic member 21. This stress may have anisotropy in the X-Y plane. The anisotropy may be induced by various configurations.

For example, as shown in FIG. 1 and FIG. 2, the magnetic device 110 may further include a first conductive member 51. The first conductive member 51 includes a first conductive portion 51a, a second conductive portion 51b, and a third conductive portion 51c. The third conductive portion 51c is provided between the first conductive portion 51a and the second conductive portion 51b. A second direction D2 from the first conductive portion 51a to the second conductive portion 51b crosses the first direction D1. The second direction D2 is, for example, the X-axis direction.

As shown in FIG. 2, the first conductive portion 51a and the second conductive portion 51b are present on both sides of the position of the first element portion 10E in the X-axis direction. On the other hand, the first conductive member 51 is not present on both sides of the position of the first element portion 10E in the Y-axis direction. In this way, anisotropy exists in the X-Y plane. This may induce anisotropy in the stress. For example, the magnetization of the first magnetic member 21 may be controlled by the stress anisotropy.

In another example, as described below, an insulating member may be provided around the first element portion 10E, and the configuration of the insulating member may vary within the X-Y plane. This may induce anisotropy in the stress. For example, the magnetization of the first magnetic member 21 may be controlled by the stress anisotropy.

In further another example, anisotropy may be provided in the shape of at least one of the first non-magnetic member 31 or the first magnetic member 21. This may induce anisotropy in the stress. For example, the magnetization of the first magnetic member 21 may be controlled by the stress anisotropy.

For example, as shown in FIG. 2, the length 31y of the first non-magnetic member 31 along the third direction may be different from the length 31x of the first non-magnetic member 31 along the second direction D2. The third direction D3 crosses a plane including the first direction D1 and the second direction D2. The third direction D3 is, for example, the Y-axis direction.

In one example, the length 31y is longer than the length 31x. This results in in-plane anisotropy in the stress generated in the first non-magnetic member 31.

For example, as shown in FIG. 2, the length 21y of first magnetic member 21 along third direction D3 may be different from the length 21x of first magnetic member 21 along second direction D2. For example, the length 21y is longer than the length 21x. This causes in-plane anisotropy in the stress applied to first magnetic member 21.

Due to the in-plane anisotropy of the stress applied to first magnetic member 21, in-plane anisotropy in the lattice length of first magnetic member 21 may be generated.

For example, a third direction lattice length along the third direction D3 of at least a part of the first magnetic member 21 may be different from a second direction lattice length along the second direction D2 of at least a part of the first magnetic member 21. For example, the third direction lattice length is longer than the second direction lattice length.

In a case where the third direction lattice length is longer than the second direction lattice length, the first magnetic member 21 is pulled in the third direction D3. At this time, the first magnetic member 21 is compressed in the second direction D2.

In a case where the third direction lattice length is shorter than the second direction lattice length, the first magnetic member 21 is pulled in the second direction D2. At this time, the first magnetic member 21 is compressed in the third direction D3.

In a case where the magnetostriction constant of the first magnetic member 21 is positive, the magnetization of the first magnetic member 21 is along the direction of tension. In a case where the magnetostriction of the first magnetic member 21 is negative, the magnetization of the first magnetic member 21 is along the direction of compression.

In the embodiment, for example, stress is applied to the first magnetic member 21 by the first non-magnetic member 31. As described above, anisotropy of the stress may be generated by at least one of the shape of the first conductive member 51, the configuration of the insulating member provided around the first element portion 10E, the shape of the first non-magnetic member 31, or the shape of the first magnetic member 21. By generating anisotropic stress in the first magnetic member 21, the magnetization of the first magnetic member 21 is stably controlled. Various examples of anisotropy induced in the stress will be described later.

Stress is introduced to the first magnetic member 21 due to the influence of the first non-magnetic member 31. The stress may vary along the Z-axis direction depending on the distance from the first non-magnetic member 31. The lattice length may vary along with the stress. For example, the lattice length of the first magnetic member 21 may vary along the Z-axis direction. The stress applied from the first non-magnetic member 31 may decrease as the distance from the first non-magnetic member 31 increases.

As shown in FIG. 1, for example, the first magnetic member 21 includes a first position 21a and a second position 21b. The second position 21b is between the first position 21a and the first non-magnetic member 31. A first position lattice length along a crossing direction crossing the first direction D1 at the first position 21a is different from a second position lattice length along the crossing direction at the second position 21b. The crossing direction is, for example, any direction along the X-Y plane (for example, the Y-axis direction). The first position 21a is far from the first non-magnetic member 31. The second position 21b is close to the first non-magnetic member 31.

For example, in a case where the first magnetic member 21 receives a tensile stress, the second position lattice length is longer than the first position lattice length.

For example, in a case where the first magnetic member 21 receives a compressive stress, the second position lattice length is shorter than the first position lattice length.

As described above, the first material includes the first element (one of the first type element and the second type element, for example Ru) and a second element (at least one selected from the group consisting of oxygen and nitrogen). For example, the introduction of the second element into a member including the first element causes the volume of the member to change (for example, increase or decrease). It is preferable that the second element is introduced uniformly in the thickness direction of the first non-magnetic member 31. This makes it easier for a large stress to be applied from the first non-magnetic member 31 to the first magnetic member 21.

As shown in FIG. 1, the first non-magnetic member 31 includes a first non-magnetic portion 31a and a second non-magnetic portion 31b. The first non-magnetic portion 31a includes a first face 31f. The second non-magnetic portion 31b includes a second face 31g. The first face 31f faces the first magnetic member 21, for example. The first face 31f contacts the first magnetic member 21, for example. The first face 31f is between the first magnetic member 21 and the second face 31g in the first direction D1. The first non-magnetic portion 31a is a deep portion. The second non-magnetic portion 31b is a shallow portion.

A difference between a concentration of the second element in the first non-magnetic portion 31a (first concentration) and a concentration of the second element in the second non-magnetic portion 31b (second concentration) is small. For example, a first ratio of an absolute value of a difference between the first concentration and the second concentration to the first concentration is equal to or less than 0.2.

For example, the second element (oxygen and/or nitrogen) is introduced without a large difference in concentration between the first non-magnetic portion 31a (deep portion) and the second non-magnetic portion 31b (shallow portion). This allows a large stress to be obtained stably.

In the embodiment, a part of the first magnetic member 21 may include the second element. For example, the concentration of the second element in the first magnetic member 21 may decrease with increasing distance from the first non-magnetic member 31. As already explained, the first magnetic member 21 includes the first position 21a and the second position 21b. The second position 21b is between the first position 21a and the first non-magnetic member 31. The concentration of the second element in the second position 21b is higher than the concentration of the second element in the first position 21a. Or, the first position 21a does not include oxygen.

In one example of forming the first non-magnetic member 31, after forming a film including the first element, the film may be treated with a gas including the second element. For example, when the first element is Ru and the second element is oxygen, a set of forming a Ru film with 1 nm thickness and treating with oxygen may be repeated plurality of times. Oxygen is incorporated into the Ru film by treating the Ru film with 1 nm thickness with oxygen. By repeating these sets plurality of times, oxygen is introduced into each of the plurality of Ru films at a stable high concentration. By repeating the above set ten times, the first non-magnetic member 31 with a thickness of about 10 nm is obtained. For example, a low first ratio is easily obtained. Heat treatment may be performed appropriately.

As described above, the first non-magnetic member 31 may include the second material. In this case, the difference between the concentration of the third element in the first non-magnetic portion 31a and the concentration of the third element in the second non-magnetic portion 31b is small. For example, a first ratio of the absolute value of the difference between these concentrations to the concentration of the third element in the first non-magnetic portion 31a is 0.2 or less.

The difference between the concentration of the third element in the first non-magnetic portion 31a and the concentration of the fourth element in the second non-magnetic portion 31b is small. For example, a first ratio of the absolute value of the difference between these concentrations to the concentration of the fourth element in the first non-magnetic portion 31a is 0.2 or less.

In the first non-magnetic member 31, for example, a film including the third element (at least one selected from the group consisting of Pt, Cu, and Hf) and a film including a fourth element (Al) may be alternately provided, and a heat treatment may be performed.

In a case where the first non-magnetic member 31 includes Al and Pt, at least one of Pt₂Al₃ and PtAl₂ may be formed by heat treatment at not less than 300° C. and not more than 550° C. The first non-magnetic member 31 may include, for example, an intermetallic compound. Stress occurs due to the formation of the intermetallic compound.

In a case where the first non-magnetic member 31 includes Al and Cu, a phase transition may occur by heat treatment at not less than 200° C. and not more than 400° C. For example, Al-4Cu may be formed.

In a case where the first non-magnetic member 31 includes Al and Hf, HfAl₃ may be formed by heat treatment at not less than 350° C. and not more than 650° C. For example, a phase transition occurs from the a phase to the p phase.

As described above, stress is also generated in a case where the second material described above is applied to the first non-magnetic member 31. For example, after the film that becomes the first non-magnetic member 31 is formed, a heat treatment is performed at not less than 200° C. and not more than 650° C. The temperature of the heat treatment may be, for example, not less than 300° C. and not more than 400° C. This condition provides good compatibility with the memory manufacturing process, for example. Stress is generated by the heat treatment after the film is formed. The stress is thought to be related to, for example, mutual diffusion of elements, changes in crystal structure, and/or changes in lattice constant due to the heat treatment.

In a case where a film including the third element and a film including the fourth element are alternately stacked on the first magnetic member 21, the film including the third element may be in contact with the first magnetic member 21. The fourth element (Al) is relatively more likely to move (diffuse) than the third element. By having the film including the third element in contact with the first magnetic member 21, the movement of the fourth element can be suppressed.

In a case also where the above-mentioned second material is applied to the first non-magnetic member 31, the configuration described for the first material may be provided.

In the embodiment, a thickness t31 (see FIG. 1) of the first non-magnetic member 31 along the first direction D1 is, for example, not less than 1 nm and not more than 50 nm. By the thickness t31 being 1 nm or more, for example, a stable stress is easily obtained, and the magnetization of the first magnetic member 21 can be stably controlled. By the thickness t31 being 50 nm or less, for example, the processing of the element becomes easier, and fine elements can be easily obtained.

In an embodiment, a thickness t11 (see FIG. 1) of the first magnetic layer 11 along the first direction D1 may be, for example, not less than 0.5 nm and not more than 10 nm. The thickness t15 (see FIG. 1) of the first intermediate layer 15 along the first direction D1 may be, for example, not less than 0.3 nm and not more than 3 nm.

As already described, the magnetic device 110 may further include a first conductive member 51. At least a part of the first conductive member 51 may be in contact with the first magnetic layer 11. The first conductive member 51 includes, for example, at least one selected from the group consisting of Ta, W, Pt, Hf, Re, Os, Ir, Pd, Cu, Ag, and Au.

For example, a current flowing through the first conductive member 51 acts on the first magnetic layer 11. This allows the magnetization of the first magnetic layer 11 (magnetic free layer) to be controlled. For example, the magnetization of the first magnetic layer 11 is controlled by spin-orbit torque.

As shown in FIG. 2, the magnetic device 110 may include a controller 70. The controller 70 is electrically connected to, for example, the first conductive member 51 and the first non-magnetic member 31.

As already explained (see FIG. 2), the first conductive member 51 includes a first conductive portion 51a, a second conductive portion 51b, and a third conductive portion 51c. The third conductive portion 51c is provided between the first conductive portion 51a and the second conductive portion 51b. The boundary between these portions may be unclear.

The first magnetic layer 11 is between the third conductive portion 51c and the first non-magnetic member 31 in the first direction D1. The first magnetic layer 11 overlaps the third conductive portion 51c in the first direction D1. The first magnetic layer 11 does not overlap the first conductive portion 51a and the second conductive portion 51b in the first direction D1.

The controller 70 can supply a first current i1 between the first conductive portion 51a and the second conductive portion 51b. The first current i1 may be oriented from the first conductive portion 51a to the second conductive portion 51b, or from the second conductive portion 51b to the first conductive portion 51a. The controller 70 can apply a voltage Val between the first conductive member 51 and the first non-magnetic member 31.

The electrical resistance between the first conductive member 51 and the first non-magnetic member 31 can be changed (controlled) by the direction of the first current i1 and the voltage Val between the first conductive member 51 and the first non-magnetic member 31. For example, when the voltage Val is either negative or positive, the magnetization of the first magnetic layer 11 is likely to change in response to the first current i1. For example, when the voltage Val is the other of negative and positive, the magnetization of the first magnetic layer 11 is unlikely to change even when the first current i1 is supplied. With this configuration, the magnetization of the first magnetic layer 11 can be stably controlled. The electrical resistance can be stably controlled.

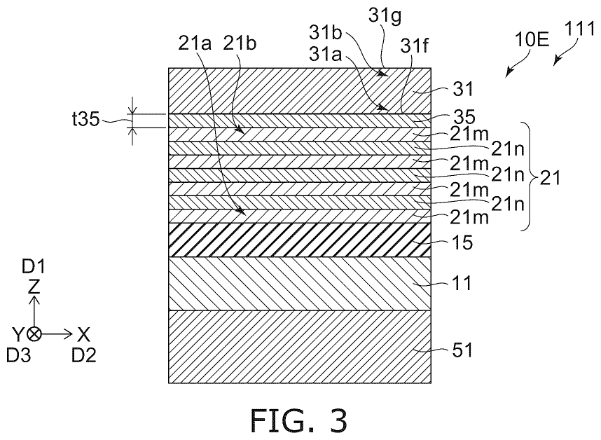

FIG. 3 is a schematic cross-sectional view illustrating a magnetic device according to the first embodiment.

As shown in FIG. 3, a magnetic device 111 according to the embodiment includes the first element portion 10E. The first element portion 10E includes a first intermediate member 35. The configuration of the magnetic device 111 except for this may be similar to the configuration of the magnetic device 110.

For example, in the magnetic device 111, the first element portion 10E includes the first magnetic layer 11, the first non-magnetic member 31, the first magnetic member 21, the first intermediate layer 15, and the first intermediate member 35. The first non-magnetic member 31 is conductive. The direction from the first magnetic layer 11 to the first non-magnetic member 31 is along the first direction D1. The first magnetic member 21 is provided between the first magnetic layer 11 and the first non-magnetic member 31. The first intermediate layer 15 is provided between the first magnetic layer 11 and the first magnetic member 21, and is non-magnetic. The first intermediate member 35 is provided between the first magnetic member 21 and the first non-magnetic member 31 and is in contact with the first magnetic member 21 and the first non-magnetic member 31.

The first non-magnetic member 31 includes at least one of the first material and the second material. The first material includes a first element including one of the first type element and the second type element, and the second element including at least one selected from the group consisting of oxygen and nitrogen. The first type element includes at least one selected from the group consisting of Ru, Ta, Mo, W, Hf, Cr, Cu, Pd, V, Ti, and Zn. The second type element includes at least one selected from the group consisting of Mg and Al. The second material includes the third element including at least one selected from the group consisting of Pt, Cu, and Hf, and the fourth element including Al.

The first intermediate member 35 includes at least one of a first intermediate material, a second intermediate material, or a third intermediate material. The first intermediate material includes a fifth element including at least one selected from the group consisting of Mg, Al, Ta, Mo, Nb, Hf, and Ru, and oxygen. The second intermediate material includes a sixth element including at least one selected from the group consisting of B, Si, Ga, and Ti, and nitrogen. The third intermediate material includes at least one selected from the group consisting of W, Re, Os, Ta, Mo, Ir, Ru, and Hf.

The first intermediate member 35 includes, for example, at least one selected from the group consisting of MgO, Al₂O₃, TaO, MoO₃, NbO, HfO, RuO₂, and Ta₂O₅. Thus, the first intermediate member 35 may include an oxide. In this case, the thickness t35 (see FIG. 3) of the first intermediate member 35 is, for example, 0.5 nm or less.

The first intermediate member 35 includes, for example, at least one selected from the group consisting of BN, SiN, GaN, and TiN. Thus, the first intermediate member 35 may include a nitride. In this case, the thickness t35 of the first intermediate member 35 is, for example, 1 nm or less.

The first intermediate member 35 may include, for example, at least one selected from the group consisting of a W region, a Re region, an Os region, a Ta region, a Mo region, an Ir region, a Ru region, and an Hf region. The melting points of these elements are high. These materials are difficult to mix with elements such as Co or Fe provided in the first magnetic member 21. For example, the third intermediate material is a non-solid-soluble metal with respect to Co or Fe.

By providing the first intermediate member 35, it is possible to suppress the movement of elements included in the first non-magnetic member 31 (elements included in the first material or the second material) to the first magnetic member 21. The first intermediate member 35 is, for example, a diffusion suppression layer.

By providing the first intermediate member 35, for example, the first magnetic member 21 becomes stable. Stable characteristics are easily obtained.

In a case where a film including the third element and a film including the fourth element are alternately stacked in the first intermediate member 35, the film including the third element may be in contact with the first intermediate member 35. The fourth element (Al) is relatively more likely to move (diffuse) than the third element. By having the film including the third element in contact with the first intermediate member 35, the movement of the fourth element can be further suppressed.

Below, several examples will be described in which stress anisotropy is introduced by an insulating member provided around the first element portion 10E.

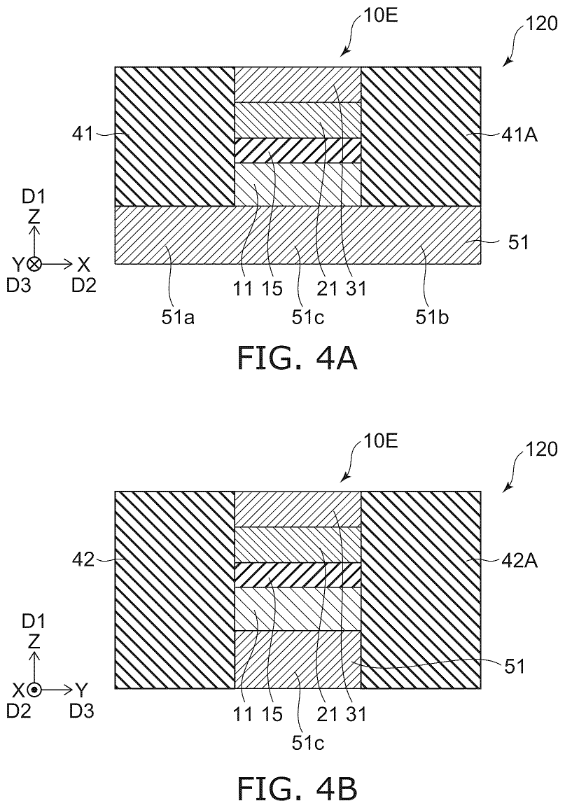

FIGS. 4A and 4B are schematic cross-sectional views illustrating a magnetic device according to the first embodiment.

As shown in FIGS. 4A and 4B, a magnetic device 120 according to the embodiment includes a first insulating member 41 and a second insulating member 42 in addition to the first element portion 10E. The configuration of the magnetic device 120 except for this may be similar to the configuration of the magnetic device 110. In this example, the magnetic device 120 includes a first opposing insulating member 41A and a second opposing insulating member 42A.

A direction from the first insulating member 41 to the first element portion 10E is along the second direction D2. The first element portion 10E is between the first insulating member 41 and the first opposing insulating member 41A in the second direction D2. For example, the first insulating member 41 contacts the first conductive portion 51a. For example, the first opposing insulating member 41A contacts the second conductive portion 51b. The first insulating member 41 contacts at least a part of the first element portion 10E. The first opposing insulating member 41A contacts at least a part of the first element portion 10E.

As shown in FIG. 4B, a direction from the second insulating member 42 to the first element portion 10E is along the third direction D3. The first element portion 10E is between the second insulating member 42 and the second opposing insulating member 42A in the third direction D3. In this example, the second insulating member 42 contacts at least a part of the first element portion 10E. The second opposing insulating member 42A contacts at least a part of the first element portion 10E.

The material of the second insulating member 42 is different from the material included in the first insulating member 41. This induces anisotropy in the stress. For example, anisotropic stress is applied to the first magnetic member 21. For example, the material of the second opposing insulating member 42A is different from the material included in the first opposing insulating member 41A. This causes anisotropic stress to be applied to the first magnetic member 21.

The Young's modulus of the material of the second insulating member 42 is different from the Young's modulus of the material included in the first insulating member 41.

For example, the Young's modulus of the material of the second insulating member 42 is lower than the Young's modulus of the material included in the first insulating member 41. In this case, the magnetostriction constant of the first magnetic member 21 may be positive. For example, the lattice length of the first magnetic member 21 along the third direction D3 is longer than the lattice length of the first magnetic member 21 along the second direction D2.

In another example, the Young's modulus of the material of the second insulating member 42 is higher than the Young's modulus of the material included in the first insulating member 41. In this case, the magnetostriction constant of the first magnetic member 21 may be negative. For example, the lattice length of the first magnetic member 21 along the third direction D3 is shorter than the lattice length of the first magnetic member 21 along the second direction D2.

The first insulating member 41 includes, for example, at least one selected from the group consisting of oxygen and nitrogen, and at least one selected from the group consisting of silicon and aluminum. The second insulating member 42 includes, for example, carbon. The second insulating member 42 may include, for example, carbon, at least one selected from the group consisting of oxygen and nitrogen, and at least one selected from the group consisting of silicon and aluminum. The first insulating member 41 does not include, for example, substantially any carbon. Or, the concentration of carbon included in the first insulating member 41 is lower than the concentration of carbon included in the second insulating member 42.

The material of the first opposing insulating member 41A may be the same as the material of the first insulating member 41. The material of the second opposing insulating member 42A may be the same as the material of the second insulating member 42.

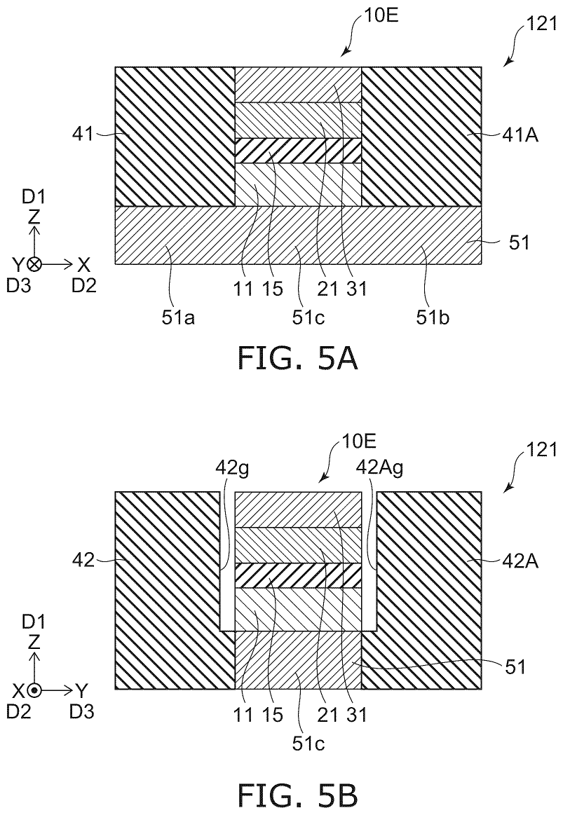

FIGS. 5A and 5B are schematic cross-sectional views illustrating the magnetic device according to the first embodiment.

As shown in FIGS. 5A and 5B, a magnetic device 121 according to the embodiment includes the first insulating member 41 and the second insulating member 42 in addition to the first element portion 10E. The configuration of the magnetic device 121 except for this may be similar to the configuration of the magnetic device 111.

In the magnetic device 121, the direction from the first insulating member 41 to the first element portion 10E is along the second direction D2. The first insulating member 41 is in contact with at least a part of the first element portion 10E. The direction from the second insulating member 42 to the first element portion 10E is along the third direction D3.

In the magnetic device 121, a gap 42g is provided between the second insulating member 42 and the first element portion 10E. Such a first insulating member 41 and a second insulating member 42 (gap 42g) induces anisotropy in the stress. For example, anisotropic stress is applied to the first magnetic member 21.

For example, in the second direction D2, the first element portion 10E may be provided between the first insulating member 41 and the first opposing insulating member 41A. The first opposing insulating member 41A contacts the first element portion 10E. In the third direction D3, the first element portion 10E may be provided between the second insulating member 42 and the second opposing insulating member 42A. A gap 42Ag is provided between the first element portion 10E and the second opposing insulating member 42A. Anisotropy is induced in the stress. For example, an anisotropic stress is applied to the first magnetic member 21.

In the magnetic device 121, for example, the magnetostriction constant of the first magnetic member 21 may be positive. For example, the lattice length of the first magnetic member 21 along the third direction D3 is longer than the lattice length of the first magnetic member 21 along the second direction D2.

In the embodiment, in a case where the magnetostriction constant of the first magnetic member 21 is negative, a gap may be provided between the first insulating member 41 and the first element portion 10E. For example, the lattice length of the first magnetic member 21 along the third direction D3 is shorter than the lattice length of the first magnetic member 21 along the second direction D2.

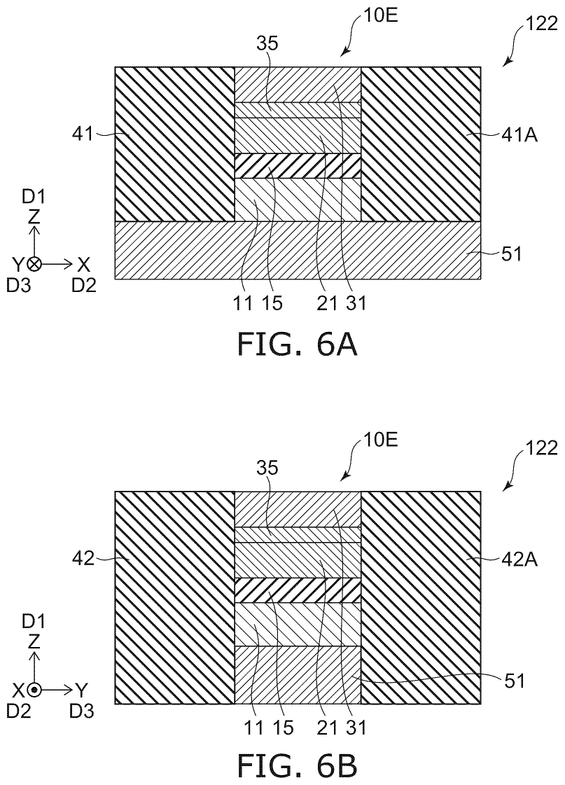

FIGS. 6A and 6B are schematic cross-sectional views illustrating the magnetic device according to the first embodiment.

As shown in FIGS. 6A and 6B, a magnetic device 122 according to the embodiment includes the first insulating member 41 and the second insulating member 42 in addition to the first element portion 10E. The configuration of the magnetic device 122 except for this may be similar to the configuration of the magnetic device 111. For example, the first element portion 10E includes the first intermediate member 35. The material of the second insulating member 42 is different from the material of the first insulating member 41.

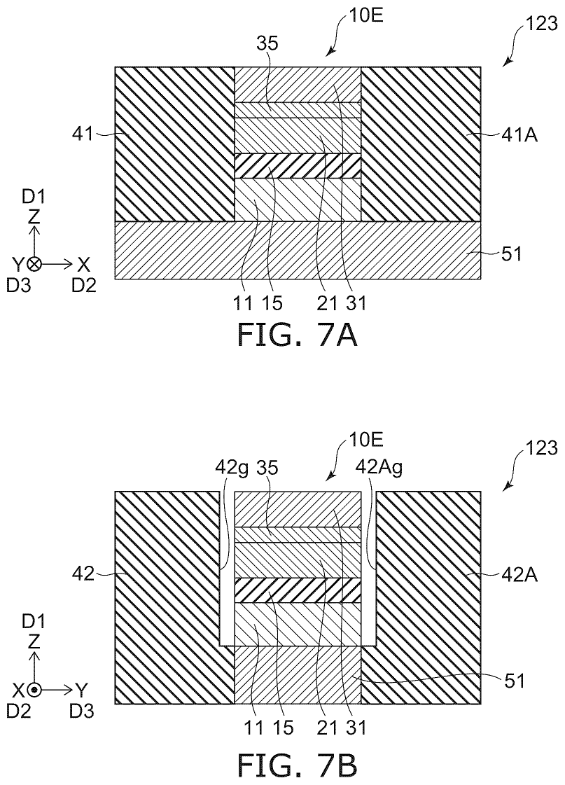

FIGS. 7A and 7B are schematic cross-sectional views illustrating the magnetic device according to the first embodiment.

As shown in FIG. 7A and FIG. 7B, a magnetic device 123 according to the embodiment includes the first insulating member 41 and the second insulating member 42 in addition to the first element portion 10E. The configuration of the magnetic device 123 except for this may be similar to the configuration of the magnetic device 111. For example, the first element portion 10E includes the first intermediate member 35. The first insulating member 41 contacts the first element portion 10E. A gap 42g is provided between the second insulating member 42 and the first element portion 10E.

In the magnetic device 122 and the magnetic device 123, anisotropy is induced in the stress. For example, anisotropic stress is applied to the first magnetic member 21.

### Second Embodiment

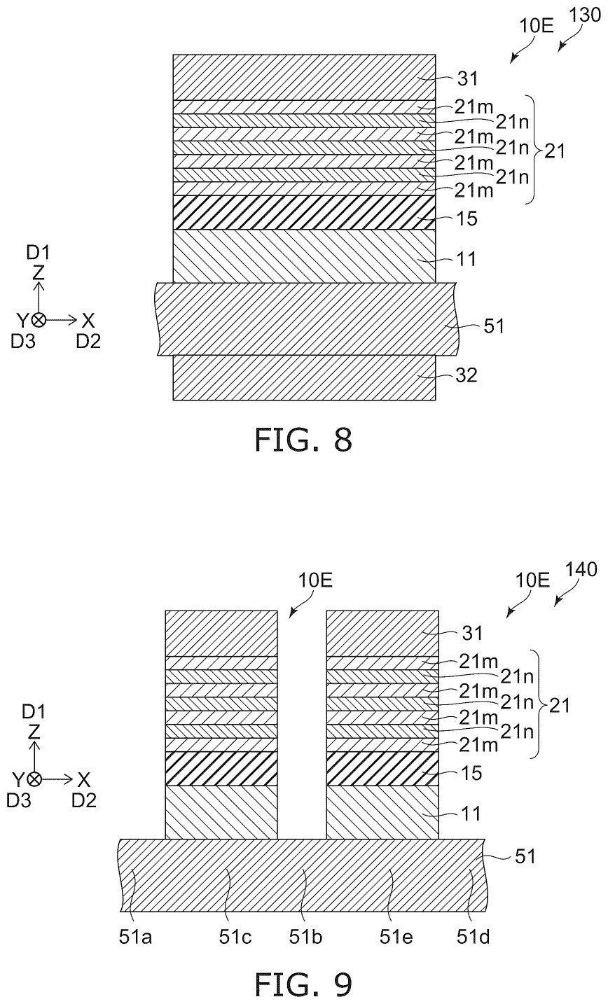

FIG. 8 is a schematic cross-sectional view illustrating a magnetic device according to a second embodiment.

As shown in FIG. 8, a magnetic device 130 according to the embodiment further includes a second non-magnetic member 32 in addition to the first element portion 10E. The configuration of the magnetic device 130 except for this may be similar to that of the magnetic device 110.

The first magnetic layer 11 is between the second non-magnetic member 32 and at least a part of the first conductive member 51 in the first direction D1. The second non-magnetic member 32 may be in contact with the first conductive member 51. The second non-magnetic member 32 includes at least one of the third material and the fourth material. The third material includes one of a third element and a fourth element, and at least one selected from the group consisting of oxygen and nitrogen. The third element includes at least one selected from the group consisting of Ru, Ta, Mo, W, Hf, Cr, Cu, Pd, V, Ti, and Zn. The fourth element includes at least one selected from the group consisting of Mg and Al. The fourth material includes at least one selected from the group consisting of Pt, Cu, and Hf, and Al.

The second non-magnetic member 32 may, for example, apply stress to the first conductive member 51 and the first element portion 10E. The second non-magnetic member 32 may be conductive or non-conductive. The second non-magnetic member 32 provides a magnetic device capable of more stable operation. The second non-magnetic member 32 may be applied to any of the magnetic devices described in relation to the first embodiment.

### Third Embodiment

FIG. 9 is a schematic cross-sectional view illustrating a magnetic device according to a third embodiment.

As shown in FIG. 9, a magnetic device 140 according to the embodiment includes a plurality of first element portions 10E. The magnetic device 140 can be used, for example, as a memory circuit. The magnetic device 120 can be used, for example, as a logic circuit. The number of the plurality of first element portions 10E is arbitrary.

For example, the first conductive member 51 may further include a fourth conductive portion 51d and a fifth conductive portion 51e. The second conductive portion 51b is between the first conductive portion 51a and the fourth conductive portion 51d. The fifth conductive portion 51e is between the second conductive portion 51b and the fourth conductive portion 51d. One of the plurality of first element portions 10E is provided in the third conductive portion 51c. Another one of the plurality of first element portions 10E is provided in the fifth conductive portion 51e.

The configuration of the magnetic device 140 may be applied to any magnetic device according to the first or second embodiment.

The embodiment may include the following configurations:

### (Configuration 1)

A magnetic device, comprising:
a first element portion, the first element portion including:
   a first magnetic layer;
   a non-magnetic member being conductive, a direction from the first magnetic layer to the first non-magnetic member being along a first direction;
   a first magnetic member provided between the first magnetic layer and the first non-magnetic member; and
   a first intermediate layer being non-magnetic, the first intermediate layer being provided between the first magnetic layer and the first magnetic member,
the first material including a first element and a second element, the first element including one of a first type element and a second type element, the second element including at least one element selected from the group consisting of oxygen and nitrogen,
the first type element including at least one element selected from the group consisting of Ru, Ta, Mo, W, Hf, Cr, Cu, Pd, V, Ti, and Zn,
the second type element including at least one selected from the group consisting of Mg and Al, and
the second material including a third element and a fourth element, the third element including at least one selected from the group consisting of Pt, Cu, and Hf, the fourth element including Al.

### (Configuration 2)

A magnetic device, comprising:
a first element portion, the first element portion including:
   a first magnetic layer;
   a non-magnetic member being conductive, a direction from the first magnetic layer to the first non-magnetic member being along a first direction;
   a first magnetic member provided between the first magnetic layer and the first non-magnetic member;
   a first intermediate layer being non-magnetic, the first intermediate layer being provided between the first magnetic layer and the first magnetic member, and
   a first intermediate member provided between the first magnetic member and the first non-magnetic member and being in contact with the first magnetic member and the first non-magnetic member;
the first material including a first element and a second element, the first element including one of a first type element and a second type element, the second element including at least one element selected from the group consisting of oxygen and nitrogen,
the first type element including at least one element selected from the group consisting of Ru, Ta, Mo, W, Hf, Cr, Cu, Pd, V, Ti, and Zn,
the second type element including at least one selected from the group consisting of Mg and Al,
the second material including a third element and a fourth element, the third element including at least one selected from the group consisting of Pt, Cu, and Hf, the fourth element including Al,
the first intermediate member including at least one of a first intermediate material, a second intermediate material, or a third intermediate material,
the first intermediate material including oxygen and a fifth element including at least one selected from the group consisting of Mg, Al, Ta, Mo, Nb, Hf, and Ru,
the second intermediate material including nitrogen and a sixth element including at least one selected from the group consisting of B, Si, Ga, and T, and
the third intermediate material including at least one selected from the group consisting of W, Re, Os, Ta, Mo, Ir, Ru, and Hf.

### (Configuration 3)

The magnetic device according to Configuration 1 or 2, further comprising:
a first conductive member,
the first conductive member including a first conductive portion, a second conductive portion, and a third conductive portion,
the third conductive portion being provided between the first conductive portion and the second conductive portion in a second direction crossing the first direction,
the first magnetic layer being between the third conductive portion and the first non-magnetic member in the first direction,
the first conductive member including at least one selected from the group consisting of Ta, W, Pt, Hf, Re, Os, Ir, Pd, Cu, Ag, and Au.

### (Configuration 4)

The magnetic device according to Configuration 3, further comprising:
a first insulating member and a second insulating member,
a direction from the first insulating member to the first element portion being along the second direction,
the first insulating member being in contact with at least a part of the first element portion,
a direction from the second insulating member to the first element portion being along a third direction crossing a plane including the first direction and the second direction,
the second insulating member being in contact with at least a part of the first element portion, and
a material of the second insulating member being different from a material included in the first insulating member.

### (Configuration 5)

The magnetic device according to Configuration 4, wherein
a Young's modulus of the material of the second insulating member is different from a Young's modulus of the material included in the first insulating member.

### (Configuration 6)

The magnetic device according to Configuration 3, further comprising:
a first insulating member and a second insulating member,
a direction from the first insulating member to the first element portion being along the second direction,
the first insulating member being in contact with at least a part of the first element portion,
a direction from the second insulating member to the first element portion being along a third direction crossing a plane including the first direction and the second direction, and
a gap being provided between the second insulating member and the first element portion.

### (Configuration 7)

The magnetic device according to Configuration 5, wherein
a magnetostriction constant of the first magnetic member is positive, and
the Young's modulus of the material of the second insulating member is lower than the Young's modulus of the material included in the first insulating member.

### (Configuration 8)

The magnetic device according to Configuration 7, wherein a magnetostriction constant of the first magnetic member is positive.

### (Configuration 9)

The magnetic device according to Configuration 1 or 2, wherein
a length of the first non-magnetic member along a third direction is longer than a length of the first non-magnetic member along a second direction,
the second direction crosses the first direction, and
the third direction crosses a plane including the first direction and the second direction.

### (Configuration 10)

The magnetic device according to Configuration 9, further comprising:
a first conductive member,
the first conductive member including a first conductive portion, a second conductive portion, and a third conductive portion,
the third conductive portion being provided between the first conductive portion and the second conductive portion in the second direction,
the first magnetic layer being between the third conductive portion and the first non-magnetic member in the first direction, and
the first conductive member including at least one selected from the group consisting of Ta, W, Pt, Hf, Re, Os, Ir, Pd, Cu, Ag, and Au.

### (Configuration 11)

The magnetic device according to Configuration 9 or 10, wherein a magnetostriction constant of the first magnetic member is positive.

### (Configuration 12)

The magnetic device according to any one of Configurations 4-11, wherein
a third direction lattice length along the third direction of at least a part of the first magnetic member is longer than a second direction lattice length along the second direction of at least a part of the first magnetic member.

### (Configuration 13)

The magnetic device according to any one of Configurations 1 to 12, wherein
the first magnetic member includes a plurality of first magnetic films and a plurality of first non-magnetic films, and
in the first direction, one of the plurality of first non-magnetic films is between one of the plurality of first magnetic films and another one of the plurality of first magnetic films.

### (Configuration 14)

The magnetic device according to Configuration 13, wherein
the first magnetic member satisfies a first condition or a second condition,
in the first condition, the one of the plurality of first non-magnetic films includes Ru, and a thickness of the one of the plurality of first non-magnetic films along the first direction is not less than 0.2 nm and not more than 2 nm, and
in the second condition, the one of the plurality of first non-magnetic films includes Ir, and the thickness of the one of the plurality of first non-magnetic films along the first direction is not less than 0.2 nm and not more than 2 nm.

### (Configuration 15)

The magnetic device according to any one of Configurations 1-14, wherein
the first non-magnetic member includes a first non-magnetic portion including a first face and a second non-magnetic portion including a second face,
the first face is between the first magnetic member and the second face in the first direction,
a first ratio of an absolute value of a difference between a first concentration of the second element in the first non-magnetic portion and a second concentration of the second element in the second non-magnetic portion to the first concentration is 0.2 or less.

### (Configuration 16)

The magnetic device according to any one of Configurations 1 to 15, wherein
the first magnetic member includes a first position and a second position,
the second position is between the first position and the first non-magnetic member,
a concentration of the second element at the second position is higher than a concentration of the second element at the first position, or the first position does not include oxygen.

### (Configuration 17)

The magnetic device according to any one of Configurations 3-8, further comprising:
a controller,
the controller being configured to supply a first current between the first conductive portion and the second conductive portion,
an electrical resistance between the first conductive member and the first non-magnetic member being configured to be changed depending on a direction of the first current and a voltage between the first conductive member and the first non-magnetic member.

### (Configuration 18)

The magnetic device according to any one of Configurations 3-8, wherein
the first magnetic member includes a first position and a second position,
the second position is between the first position and the first non-magnetic member,
a first position lattice length along a cross direction crossing the first direction at the first position being different from a second position lattice length along the cross direction at the second position.

### (Configuration 19)

The magnetic device according to Configuration 18, wherein
the second position lattice length is longer than the first position lattice length.

### (Configuration 20)

The magnetic device according to any one of configurations 3-8, further comprising:
a second non-magnetic member,
the first magnetic layer being between the second non-magnetic member and at least a part of the first conductive member in the first direction, and
the second non-magnetic member being in contact with the first conductive member,
the second non-magnetic member including at least one of a third material or a fourth material,
the third material including one of a third type element and a fourth type element, and at least one selected from the group consisting of oxygen and nitrogen,
the third type element including at least one selected from the group consisting of Ru, Ta, Mo, W, Hf, Cr, Cu, Pd, V, Ti, and Zn,
the fourth type element including at least one selected from the group consisting of Mg and Al, and
the fourth material including at least one selected from the group consisting of Pt, Cu, and Hf, and Al.

According to the embodiment, a magnetic device capable of stable operation can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the magnetic devices such as element portions, magnetic layers, non-magnetic members, magnetic members, intermediate layers, intermediate members, conductive members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all magnetic devices practicable by an appropriate design modification by one skilled in the art based on the magnetic devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

What is claimed is:

1. A magnetic device, comprising:
a first element portion, the first element portion including:
a first magnetic layer;
a non-magnetic member being conductive, a direction from the first magnetic layer to the first non-magnetic member being along a first direction;
a first magnetic member provided between the first magnetic layer and the first non-magnetic member; and
a first intermediate layer being non-magnetic, the first intermediate layer being provided between the first magnetic layer and the first magnetic member,
the first material including a first element and a second element, the first element including one of a first type element and a second type element, the second element including at least one element selected from the group consisting of oxygen and nitrogen,
the first type element including at least one element selected from the group consisting of Ru, Ta, Mo, W, Hf, Cr, Cu, Pd, V, Ti, and Zn,
the second type element including at least one selected from the group consisting of Mg and Al, and
the second material including a third element and a fourth element, the third element including at least one selected from the group consisting of Pt, Cu, and Hf, the fourth element including Al.

2. A magnetic device, comprising:
a first element portion, the first element portion including:
a first magnetic layer;
a non-magnetic member being conductive, a direction from the first magnetic layer to the first non-magnetic member being along a first direction;
a first magnetic member provided between the first magnetic layer and the first non-magnetic member;
a first intermediate layer being non-magnetic, the first intermediate layer being provided between the first magnetic layer and the first magnetic member, and
a first intermediate member provided between the first magnetic member and the first non-magnetic member and being in contact with the first magnetic member and the first non-magnetic member;
the first material including a first element and a second element, the first element including one of a first type element and a second type element, the second element including at least one element selected from the group consisting of oxygen and nitrogen,
the first type element including at least one element selected from the group consisting of Ru, Ta, Mo, W, Hf, Cr, Cu, Pd, V, Ti, and Zn,
the second type element including at least one selected from the group consisting of Mg and Al,
the second material including a third element and a fourth element, the third element including at least one selected from the group consisting of Pt, Cu, and Hf, the fourth element including Al,
the first intermediate member including at least one of a first intermediate material, a second intermediate material, or a third intermediate material,
the first intermediate material including oxygen and a fifth element including at least one selected from the group consisting of Mg, Al, Ta, Mo, Nb, Hf, and Ru,
the second intermediate material including nitrogen and a sixth element including at least one selected from the group consisting of B, Si, Ga, and T, and
the third intermediate material including at least one selected from the group consisting of W, Re, Os, Ta, Mo, Ir, Ru, and Hf.

3. The magnetic device according to claim 1, further comprising:
a first conductive member,
the first conductive member including a first conductive portion, a second conductive portion, and a third conductive portion,
the third conductive portion being provided between the first conductive portion and the second conductive portion in a second direction crossing the first direction,
the first magnetic layer being between the third conductive portion and the first non-magnetic member in the first direction,
the first conductive member including at least one selected from the group consisting of Ta, W, Pt, Hf, Re, Os, Ir, Pd, Cu, Ag, and Au.

4. The magnetic device according to claim 3, further comprising:
a first insulating member and a second insulating member,
a direction from the first insulating member to the first element portion being along the second direction,
the first insulating member being in contact with at least a part of the first element portion,
a direction from the second insulating member to the first element portion being along a third direction crossing a plane including the first direction and the second direction,
the second insulating member being in contact with at least a part of the first element portion, and
a material of the second insulating member being different from a material included in the first insulating member.

5. The magnetic device according to claim 4, wherein
a Young's modulus of the material of the second insulating member is different from a Young's modulus of the material included in the first insulating member.

6. The magnetic device according to claim 3, further comprising:
a first insulating member and a second insulating member,
a direction from the first insulating member to the first element portion being along the second direction,
the first insulating member being in contact with at least a part of the first element portion,
a direction from the second insulating member to the first element portion being along a third direction crossing a plane including the first direction and the second direction, and
a gap being provided between the second insulating member and the first element portion.

7. The magnetic device according to claim 5, wherein
a magnetostriction constant of the first magnetic member is positive, and
the Young's modulus of the material of the second insulating member is lower than the Young's modulus of the material included in the first insulating member.

8. The magnetic device according to claim 7, wherein
a magnetostriction constant of the first magnetic member is positive.

9. The magnetic device according to claim 1, wherein
a length of the first non-magnetic member along a third direction is longer than a length of the first non-magnetic member along a second direction,
the second direction crosses the first direction, and
the third direction crosses a plane including the first direction and the second direction.

10. The magnetic device according to claim 9, further comprising:
a first conductive member,
the first conductive member including a first conductive portion, a second conductive portion, and a third conductive portion,
the third conductive portion being provided between the first conductive portion and the second conductive portion in the second direction,
the first magnetic layer being between the third conductive portion and the first non-magnetic member in the first direction, and
the first conductive member including at least one selected from the group consisting of Ta, W, Pt, Hf, Re, Os, Ir, Pd, Cu, Ag, and Au.

11. The magnetic device according to claim 9, wherein a magnetostriction constant of the first magnetic member is positive.

12. The magnetic device according to claim 4, wherein
a third direction lattice length along the third direction of at least a part of the first magnetic member is longer than a second direction lattice length along the second direction of at least a part of the first magnetic member.

13. The magnetic device according to claim 1, wherein
the first magnetic member includes a plurality of first magnetic films and a plurality of first non-magnetic films, and
in the first direction, one of the plurality of first non-magnetic films is between one of the plurality of first magnetic films and another one of the plurality of first magnetic films.

14. The magnetic device according to claim 13, wherein
the first magnetic member satisfies a first condition or a second condition,
in the first condition, the one of the plurality of first non-magnetic films includes Ru, and a thickness of the one of the plurality of first non-magnetic films along the first direction is not less than 0.2 nm and not more than 2 nm, and
in the second condition, the one of the plurality of first non-magnetic films includes Ir, and the thickness of the one of the plurality of first non-magnetic films along the first direction is not less than 0.2 nm and not more than 2 nm.

15. The magnetic device according to claim 1, wherein
the first non-magnetic member includes a first non-magnetic portion including a first face and a second non-magnetic portion including a second face,
the first face is between the first magnetic member and the second face in the first direction,
a first ratio of an absolute value of a difference between a first concentration of the second element in the first non-magnetic portion and a second concentration of the second element in the second non-magnetic portion to the first concentration is 0.2 or less.

16. The magnetic device according to claim 1, wherein
the first magnetic member includes a first position and a second position,
the second position is between the first position and the first non-magnetic member,
a concentration of the second element at the second position is higher than a concentration of the second element at the first position, or the first position does not include oxygen.

17. The magnetic device according to claim 3, further comprising:
a controller,
the controller being configured to supply a first current between the first conductive portion and the second conductive portion,
an electrical resistance between the first conductive member and the first non-magnetic member being configured to be changed depending on a direction of the first current and a voltage between the first conductive member and the first non-magnetic member.

18. The magnetic device according to claim 3, wherein
the first magnetic member includes a first position and a second position,
the second position is between the first position and the first non-magnetic member,
a first position lattice length along a cross direction crossing the first direction at the first position being different from a second position lattice length along the cross direction at the second position.

19. The magnetic device according to claim 18, wherein
the second position lattice length is longer than the first position lattice length.

20. The magnetic device according to claim 3, further comprising:
a second non-magnetic member,
the first magnetic layer being between the second non-magnetic member and at least a part of the first conductive member in the first direction, and
the second non-magnetic member being in contact with the first conductive member,
the second non-magnetic member including at least one of a third material or a fourth material,
the third material including one of a third type element and a fourth type element, and at least one selected from the group consisting of oxygen and nitrogen,
the third type element including at least one selected from the group consisting of Ru, Ta, Mo, W, Hf, Cr, Cu, Pd, V, Ti, and Zn,
the fourth type element including at least one selected from the group consisting of Mg and Al, and
the fourth material including at least one selected from the group consisting of Pt, Cu, and Hf, and Al.
